(19) United States
(12) Patent Application Publication
(10) Pub. No.: US 2008/0203386 A1
(43) Pub. Date: Aug. 28, 2008

(54) Method of forming a patterned resist layer for patterning a semiconductor product

(76) Inventors: Ulrich Klostermann, Muenchen (DE); Wolfgang Raberg, Sauerlach (DE); Guenter Schmid, Hemhofen (DE); Michael Sebald, Weisendorf (DE)

Correspondence Address: SLATER & MATSIL LLP, 17950 PRESTON ROAD, SUITE 1000, DALLAS, TX, 75252, US

(21) Appl. No.: 11/712,217

(22) Filed: Feb. 28, 2007

(51) Int. Cl. H01L 21/033; G03C 5/16

(52) U.S. Cl. 257/43; 430/346; 257/E31.001

(57) ABSTRACT

A first embodiment discloses a method of forming a patterned resist layer for patterning a substrate. A resist layer is formed on or above a substrate. An inorganic layer is formed on the resist layer. The resist layer covered with the inorganic layer is lithographically exposed. The resist layer covered with the inorganic layer is patterned by etching, thereby forming a patterned resist layer.

### TECHNICAL FIELD

The invention relates to the field of semiconductor manufacture and in particular to the field of patterning of layers, on semiconductor substrates or on reticle mask substrates, for the production of integrated circuits.

### BACKGROUND

The invention refers to methods of manufacturing semiconductor products or reticle masks. Such methods usually include forming a patterned resist layer on a substrate, that is forming a mask on a substrate or on a layer on a substrate. The substrate can be a semiconductor substrate or a reticle mask substrate.

For lithographically patterning a layer deposited on or above a substrate (which may be a semiconductor product substrate as well as a reticle mask substrate), a mask has to be formed on the layer to be patterned. A mask usually is formed of organic material, based on polymer materials, for instance. Those regions of the resist material exposed during lithographic exposure are etched and removed when developing the resist layer (in case of a positive resist). Those regions of the resist layer shadowed by mask patterns of a reticle mask are maintained (in case of a positive resist). Thereby a patterned resist layer is obtained which masks those regions of the layer of the semiconductor product to be maintained subsequently during etching. The pattern of the resist layer or mask is transferred to the layer or to the substrate.

Conventionally, components provided in the resist material may outgas into the ambient atmosphere, thereby also changing the local composition of the resist material and narrowing the process window for exposing and developing (that is etching) the resist layer. In particular in case of a low pressure atmosphere or vacuum, like used in extreme ultraviolet lithography, for instance, outgassing is yet more critical. However, present EUV (extreme ultraviolet) lithography tools are just applying vacuum or low pressure atmosphere. Furthermore, outgassing components may contaminate the optical system (lens surfaces etc.) of the lithography tool, thereby reducing process window and entailing increased efforts for tool maintenance.

In case of immersion lithography, for instance, contaminations in an immersion liquid (like deionized water or another fluid medium having a high refractive index) may enter the resist material in contact with the immersion liquid. As a consequence, the composition of the resist material is influenced in like manner.

There is a need for providing an improved resist or mask with a more reliable exposure behavior upon lithographic exposure and development. There further is a need for providing methods of providing resist layers less susceptible to the effects of outgassing into an ambient atmosphere or immersion liquid and less susceptible to the entering of contaminants from the outside into the resist material.

### SUMMARY OF THE INVENTION

A first embodiment discloses a method of forming a patterned resist layer for patterning a substrate. A resist layer is formed on or above a substrate. An inorganic layer is formed on the resist layer. The resist layer covered with the inorganic layer is lithographically exposed. The resist layer covered with the inorganic layer is patterned by etching, thereby forming a patterned resist layer.

A second embodiment discloses a method of forming a mask on a semiconductor product layer of a semiconductor product. A layer on a substrate is formed. A mask layer is formed on the layer by depositing a resist layer made of organic resist material on or above the layer and depositing an inorganic layer made of inorganic material on or above the resist layer.

A third embodiment discloses a method of forming a patterned coated mask in semiconductor manufacture. An organic resist layer is deposited on a substrate or on a layer disposed on the substrate. An inorganic coating is deposited as a protection layer on the organic resist layer, thereby obtaining a coated mask, the organic resist layer covered with the inorganic coating is lithographically exposed. The inorganic coating and the organic resist layer are patterned, thereby obtaining a patterned coated mask.

In a fourth embodiment an intermediate semiconductor product includes a substrate, at least one layer arranged on or above the substrate, a resist layer arranged on or above the layer and an inorganic layer arranged on or above the resist layer.

### BRIEF DESCRIPTION OF THE DRAWINGS

Herein below embodiments of the invention are described with reference to the figures.

FIGS. 1 to 7 show process steps of an embodiment of a method according to the invention;

FIG. 8 shows an embodiment regarding the deposition of the inorganic layer;

FIG. 9 shows an embodiment regarding exposure of the resist layer covered with the inorganic layer; and

FIG. 10 shows an alternative embodiment regarding exposure of the resist layer covered with the inorganic layer.

### DETAILED DESCRIPTION OF ILLUSTRATIVE EMBODIMENTS

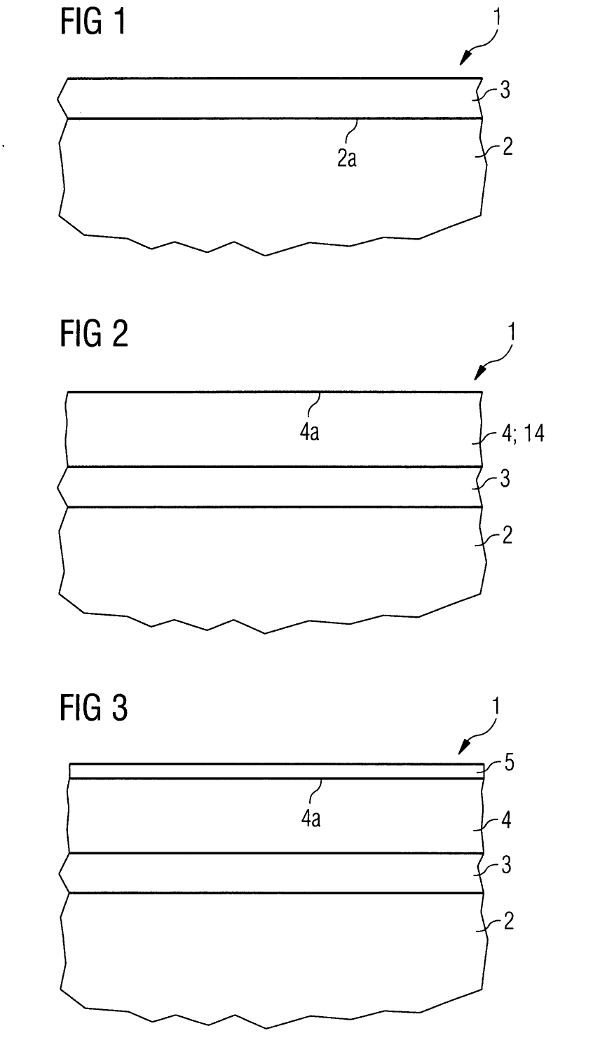

In an embodiment as illustrated in FIG. 1, a product 1 is provided which at least comprises a substrate 2. For shorter explanation, herein below with reference to FIG. 1 and to all further Figures, the product 1 is referred to as a semiconductor product 1 and the substrate is referred to as a semiconductor substrate (like a silicon substrate, for instance). However, it is to be noted that the product 1 may be a reticle mask as well and that the substrate 2 may be a reticle mask substrate as well. Merely for reasons of conciseness, reference is made in the following to the embodiment of a semiconductor substrate 2 and a semiconductor product 1.

Preferably the semiconductor product 1 further comprises a layer 3 to be patterned. According to FIG. 1 the layer is illustrated on (that is in direct contact with) a surface of the substrate 2. However, the layer 3 to be patterned may also be arranged above the substrate 2, that is at a distance from the substrate surface. In any case, on top of the intermediate semiconductor product 1, an uppermost layer 3 is present which is to be patterned in the process of semiconductor manufacture.

According to the embodiment of FIG. 2, a resist layer 4 is formed on the semiconductor product 1. Preferably the resist layer 4 is deposited directly on an upper surface of the semiconductor product layer 3 to be patterned. The semiconductor product layer 3 preferably is a layer comprising portions which are maintained in the semiconductor device formed on the substrate 2. For instance, the layer 3 may be patterned to form conductor lines, vias or other microelectronic elements. Preferably the resist layer 4 is an organic layer essentially comprising an organic material (like polymers). The resist layer 4 accordingly comprises photoactive molecules which, upon exposure, generate (acid) molecules required for dissolving the resist material upon contact with a developer medium. The resist layer 4 accordingly is a mask layer useable for forming a mask layer 14 for patterning the semiconductor product layer 3. The resist layer 4 comprises a top surface 4a opposed to the substrate 2, that is facing in the opposite direction to the interface surface of the resist layer 4 in contact with the layer 3 or the substrate 2. Conventionally the resist layer 4 as illustrated in FIG. 2 would be exposed and developed, thereby forming a mask layer 14 on layer 3. Prior to or during exposure, however, outgassing as well as contamination of the resist material with molecules from ambient atmosphere or immersion liquid may occur.

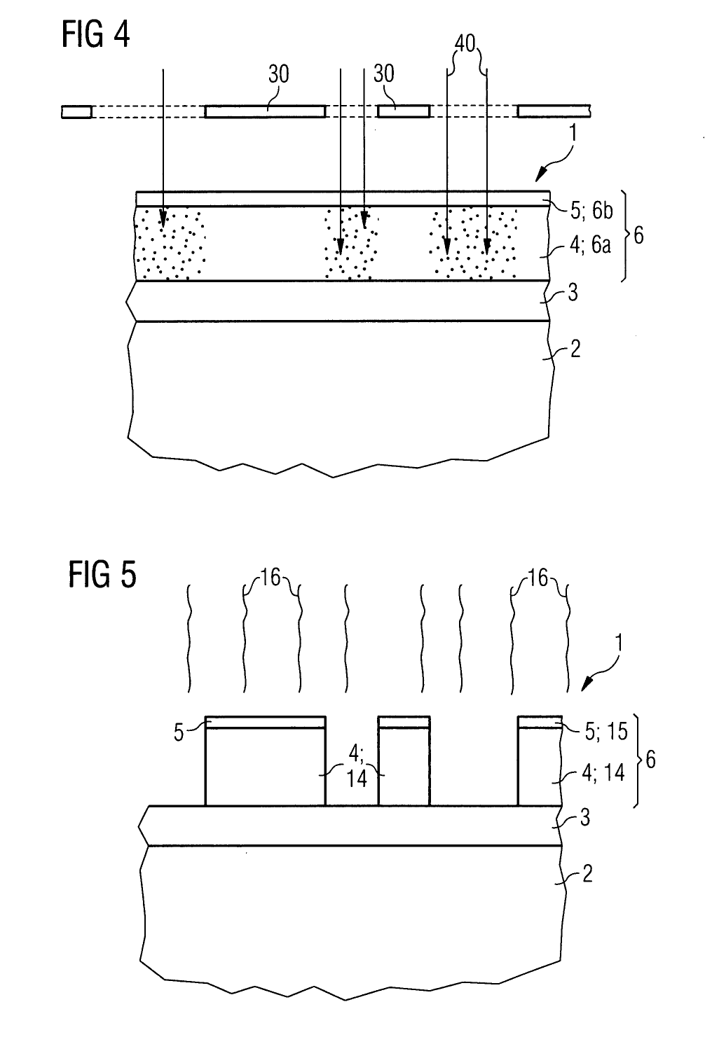

According to the embodiment of FIG. 3, however, an inorganic layer 5 is formed on the resist layer 4, thereby covering the top surface 4a of the resist layer 4. The inorganic layer 5 made of inorganic material prevents outgassing of the resist material even in a low pressure atmosphere or in a vacuum. On the other hand, the inorganic layer 5 prevents diffusion of contaminants from the outside into the resist material. Accordingly, the inorganic layer 5 formed of (or essentially comprising, as a main constituent) an organic material forms a diffusion barrier and protects the resist material from chemical and/or physical interaction with an ambient fluid. Accordingly, the inorganic layer 5 forms a protective coating of an organic resist layer 4 provided thereunder.

In contrast to hardmasks, the inorganic layer 5 is arranged on a top surface 4a of the resist material facing away from the substrate 2, that is on top of the resist layer 4.

According to the embodiment of FIG. 4, the resist material of resist layer 4 is exposed by electromagnetic radiation (like UV or EUV radiation) or by an electron or ion beam. For instance, electromagnetic radiation may be used for lithographically exposing (and subsequently patterning) the resist material. To this end, FIG. 4 schematically illustrates portions of a reticle mask pattern of the reticle 30 arranged at a distance from the semiconductor product 1. Electromagnetic light 40 passing openings between the mask pattern structures of the reticle 30 may enter the resist material of resist layer 4 and thereby locally expose the resist layer (as schematically indicated in FIG. 4 by the dotted regions within the resist layer 4). With regard to the actual arrangement used for exposing the resist layer 4, FIG. 4 is only schematical. In an actual exposure tool, an optical system will be arranged between the reticle 30 and the semiconductor product 1 covered with the resist layer 4 and the inorganic layer 5 in order to project the mask pattern of the reticle onto the resist layer 4. Furthermore, an illumination source and a further, first optical system will be provided for illuminating the reticle 30. As apparent from FIG. 4, the resist layer 4 serves as a lower mask layer 6a and the inorganic layer 5 forms an upper mask layer 6b, thereby yielding a mask layer 6 comprising an inorganic layer arranged on top of an organic layer. In other words, the mask obtained according to this embodiment of the invention is an organic mask layer 14 covered with a protective inorganic coating 15 as apparent from FIG. 5.

FIG. 5 illustrates the intermediate semiconductor product 1 after patterning (that is etching) the resist layer 4 to form the mask 6 for etching the semiconductor product layer 3 (or the substrate 2 or another layer provided in a distance from the substrate surface). After exposing the resist layer 4 as illustrated in FIG. 4, due to application of a developer medium indicated by reference number 16, the stack of layers 5 and 4 (FIG. 4) patterned, thereby forming a mask 6 comprising the patterned resist layer 4 and, according to one embodiment, also comprising maintained portions of the inorganic layer 5.

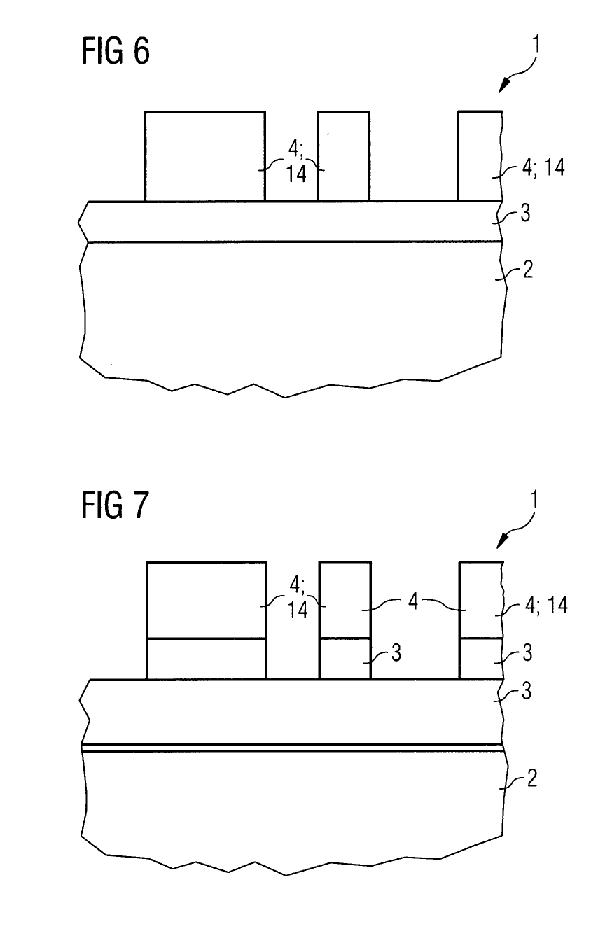

FIG. 6 illustrates an embodiment alternative to FIG. 5. According to FIG. 6 the inorganic layer 5 has been removed (for instance simultaneously with developing the resist material). To this end, the inorganic material used for the inorganic layer 5 may be chosen such that it is etched and thereby removed by the developer medium 16 employed.

As already apparent from FIG. 3, the thickness of the inorganic layer 5 is chosen smaller, preferably significantly smaller than the thickness of the resist layer 4. The inorganic layer 5 may have a thickness in the range between 0.25 and 20 nm, for instance, preferably between 1 and 3 nm. In contrast thereto, resist layers typically comprise a thickness of about 50 to 400 nm, for instance. Accordingly, the thin inorganic layer (or liner) is deposited on the resist layer 4 to provide a protective coating which is used for preventing outdiffusion, like outgassing, and diffusion of contaminants from outside into the resist layer.

Due to the small thickness of the protective coating formed by the inorganic layer 5, the inorganic layer 5 is nearly transmissive for electromagnetic radiation (or electron or ion beams) applied in order to locally expose the resist material. Accordingly, the electromagnetic radiation, the electron beam or ion beam can pass through the inorganic layer 5 and enter the resist layer 4. Alternatively, or in addition there to, an inorganic material may be chosen which as such is transmissive (even at very large thicknesses) for the respective radiation wavelength used for exposing the resist material. For instance, an inorganic material being transmissive in the UV range or EUV range may be used.

On the other hand, due to the small thickness of the inorganic layer 5, the inorganic layer 5 is easily removed in the step of patterning, that is developing the resist layer 4 (FIG. 5 or 6, alternatively). Accordingly, the inorganic material hardly influences the etching chemistry in the step of developing the resist material using the developer medium 16.

In either case, with or without maintained portions of the inorganic layer 5 on top of the resist layer 4, according to FIGS. 5 and 6 a patterned mask essentially formed of the patterned resist layer 4 is obtained. Since during exposure and prior to exposure no contaminants have been diffused into the resist material and no outgassing through the top surface of the resist layer occurred, a very reliable process of exposing and developing the resist material is obtained, thereby significantly enlarging the process window in lithography. Accordingly, defective circuits containing undesired bridgings or other defective microelectronic structures are prevented more reliably.

Generally, the inorganic layer 5 can be made of any inorganic material; in particular any metal, metal oxide, metal alloy or metal alloy oxide may be used. For instance, the inorganic layer may be formed of Al, of Al₂O₃, MgO, RuOₓ, BaO, HfOₓ, WaO, NiFe, CoFe, for instance. Furthermore, the inorganic layer 5 may comprise more than one inorganic layer. For instance, an aluminum layer sandwiched between two aluminum oxide layers may be used for the inorganic layer 5. The inorganic layer forms a sealing layer protecting the upper surface of the resist layer from contamination from outside and from outdiffusion into the ambient air.

Due to the inorganic material forming the inorganic layer 5, outdiffusion and contamination are efficiently prevented even in case of very thin inorganic layers having a thickness of below 20 nm, preferably of below 3 nm. On the other hand, due to the small thickness thereof, an organic layer does not absorb a significant amount of intensity of light used for exposing the resist. In addition, the inorganic layer is easily removable since, due to the small thickness of the inorganic liner, it is rapidly etched by the developing component, like TMAH (tetra methyle ammonium hydroxide), for instance.

In a process of an embodiment of the invention, the resist may be formed on the substrate or on a layer of the semiconductor product comprising the substrate and the layer, inter alia. After soft-baking the resist layer for hardening the resist layer, the resist layer is coated with the inorganic layer by an appropriate technique of depositing the inorganic layer. For instance, the inorganic layer may be deposited by physical vapor deposition, by chemical vapor deposition, by atomic layer deposition, by spin coating or by another technique. In case of physical vapor deposition (PVD), for instance, the deposition according to a modified embodiment may be a reactive deposition in which the plasma further comprises reactive particles like oxygen radicals, nitrogen radicals or any other kind of radicals which react with the metal to be deposited on the resist layer. Accordingly, though a metallic target is used, a metal oxide or another material (formed by oxidation, nitridation, fluorination or any other reaction of the metal with the respective radicals) is actually deposited due to the reaction of the reactive particles with the sputtered metal atoms.

Irrespective of the particular technique of depositing the inorganic layer, the method may proceed with lithographically exposing the mask 6 formed of the resist layer 4 and the inorganic layer 5. Typically, a pattern of a reticle is projected onto the mask 6. Lithographic patterning of the resist layer may be performed by means of UV lithography, EUV lithography, for instance. Alternatively, an electron beam or ion beam may be used for patterning the resist layer. In case of EUV lithography, preferably a low pressure atmosphere or vacuum is applied. Since conventionally outdiffusion is particularly critical in case of low pressure atmosphere or vacuum, a significant improvement of the process window is obtained by means of the inorganic layer on top of the resist layer.

Alternatively, lithographic exposing of a resist layer may be performed by means of immersion lithography, for instance in case of UV lithography at wavelengths of 193 or 157 nm, for instance. An immersion liquid is then applied to the upper surface of the inorganic layer, the immersion liquid filling a space between the inorganic layer, a front lens and a housing laterally surrounding the front lens and ensuring that the space between the front lens and the region of the semiconductor product surface to be patterned (that is the corresponding region of the inorganic layer thereon) is completely filled with the immersion liquid. The immersion liquid, due to its high refractive index, enlarges the process window for lithographic patterning by increasing the numerical aperture. In case of immersion lithography, the inorganic layer prevents contamination of the resist material by immersion liquid molecules. The inorganic layer further allows the use of immersion liquids which could chemically react with or enter the resist layer but which are now separated from the resist layer by means of the inorganic layer material.

Irrespective of the particular technique of lithographically exposing the resist layer, the method may then proceed with an optional post exposure baking step in order to further harden the exposed resist layer. Subsequently, the mask formed of the resist layer and the inorganic layer may be patterned using a developer medium, like an alkaline component known in the art. For instance, TMAH may be used or any other developer medium. The inorganic layer may be removed by the same developer provided for developing the resist material. Alternatively, the inorganic layer may be etched first, in a prior etching step, by means of a separate etching component. Furthermore, the developing component may be chosen such that it includes a component able to etch and thereby remove the inorganic layer. However, due to the small thickness of the inorganic layer, a moderate high selectivity of the developer medium with regard to the resist material exposed and the inorganic material may already be sufficient.

After developing and patterning the resist layer, a patterned resist layer is obtained which forms a patterned mask on the semiconductor product. The patterned mask may comprise the patterned inorganic layer. Alternatively, the inorganic layer may be absent on the patterned resist layer obtained after the developing.

Generally, it is to be noted that the resist layer referred to in the present application can also represent a stack of layers of more than one layer. For instance, the resist layer (stack) can comprise an ARC layer (anti-reflective coating) in addition or may comprise a resist bilayer or multilayer. Accordingly, the resist layer more generally represents a resist layer system comprising at least one organic resist layer. After patterning the resist layer, the inorganic layer, if still present on the patterned resist layer, may be subjected to further processing steps.

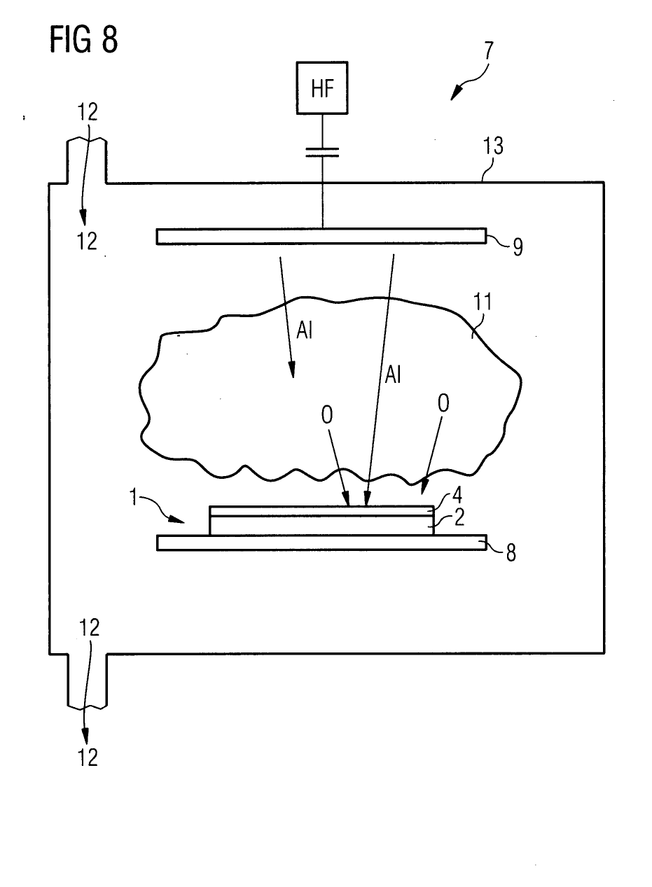

FIG. 8 illustrates an exemplary embodiment for depositing the inorganic layer on the resist layer 4. According to the embodiment of FIG. 8, a physical vapor deposition (PVD) is used for depositing the inorganic material on the organic resist layer. The semiconductor product 1 comprising the substrate 2 is arranged on a chuck 8. At an opposite region within a sputter chamber 13, a sputter target is used as a counter electrode 9, the counter electrode being connected, via a capacitive coupling, to a high frequency source HF. Due to application of a high frequency electromagnetic field, a plasma is generated in the sputter chamber 13. To this end, a sputter gas component 12 is supplied to the sputter chamber 13 and is streaming through the volume in the sputter chamber. The high frequency source HF is generating a plasma 11 formed of sputter gas particles which are impinging on the counter electrode 9 and are separating atoms therefrom. For instance, argon or krypton may be used as a sputter gas. Furthermore, a metallic or metal oxide target may be used as the counter electrode 9. In case of a metal target, the counter electrode may be formed of aluminum. Those aluminum atoms sputtered by means of the plasma are crossing through the sputter chamber volume and are deposited on the upper surface of the resist layer 4. Accordingly, the metallic inorganic layer is formed thereon, as illustrated in FIG. 3. In case of growing a metallic inorganic layer, a subsequent step of oxidizing the metallic layer may be performed, thereby obtaining a metal oxide layer as the inorganic layer 5. Alternatively, for instance in case of a reactive sputter deposition, an additional, reactive sputter gas component like oxygen may be provided to the sputter chamber volume, the oxide particles also depositing on the upper surface of the resist layer 4 and thereby growing an aluminum oxide layer (or another kind of metal oxide layer or metal alloy oxide layer) on the resist layer 4. Accordingly no subsequent step of oxidizing the inorganic layer is required. Preferably a very thin metallic layer of between 1 and 3 nm or, more generally, between 0.25 and 20 nm is grown. The sputter deposition may be a direct current magnetron sputter deposition or an alternating current magnetron sputter deposition. The distance between the substrate and the counter electrode target may be chosen appropriately, and further parameters may be chosen in an appropriate manner. According to one embodiment, an aluminum oxide layer is deposited by means of radio frequency magnetrons sputtering. Furthermore, an argon plasma or krypton plasma may be used, in particular in case of using a wavelength of 193 nm or 157 nm for subsequent exposure of the resist layer.

As mentioned above, a metallic material rather than a metal oxide material can be deposited as the inorganic layer. In this case, subsequent oxidation may be performed. For instance, the deposited metal inorganic layer may be oxidized by heating the substrate in an oxygen containing atmosphere.

After having provided the inorganic layer 5 on the resist layer 4, the resist layer is exposed.

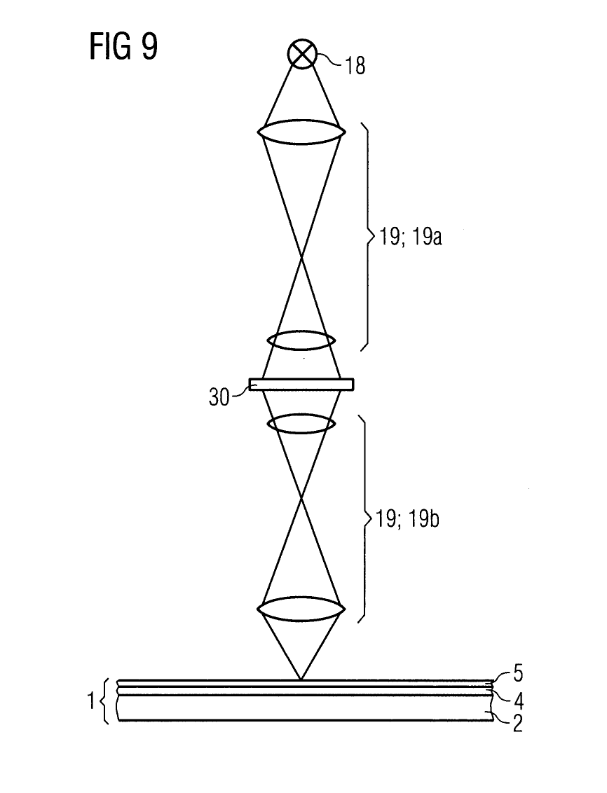

FIG. 9 illustrates an exemplary embodiment for exposing the resist layer 4. To this end, the semiconductor substrate 1 including the resist layer 4 and the inorganic layer 5 is processed by a lithography tool comprising an illumination source 18, an optical system 19 and a reticle mask 30. The optical system 19 may comprise a first optical system 19a for illuminating the reticle mask 30 and a second optical system 19b for projecting the mask pattern provided on the reticle mask 30 on to the semiconductor product 1 in order to lithographically expose the resist layer 4 provided thereon. Due to the small thickness of the inorganic layer 5 of preferably below between 10 and 20 nm—depending on the material, no significant absorption of the UV or EUV radiation occurs. The inorganic layer 5 prevents outgassing of components of the resist layer material and prevents contamination of the resist material from the ambient atmosphere, if present. Also particularly in the case of EUV lithography, the exposure is performed in a vacuum or in a low pressure atmosphere, the inorganic layer very efficiently preventing outgassing and improving performance of lithographic exposure.

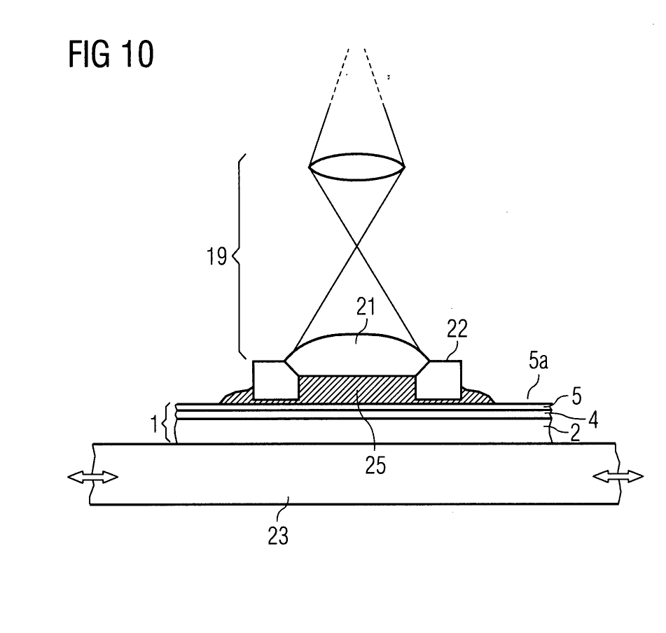

According to another embodiment of lithographic exposure illustrated in FIG. 10, immersion lithography is applied for exposing the resist layer 4. The optical system 19 preferably comprises a front lens 21 mounted in a front lens mounting 22 which is constructed to be held in close distance from the upper surface 5a of the inorganic layer 5 (or in close distance above the resist layer of the semiconductor product). The lithography tool comprises some kind of showerhead configuration providing an immersion fluid (like deionized water or another liquid having a high refractive index) into the interspace between the front lens 21 and the inorganic layer 5 in order to increase the numerical aperture. Preferably the front lens mounting 22 encapsulates a portion of volume to be filled with the immersion liquid 25. An appropriate immersion liquid supply provides fresh immersion liquid ensuring lithographic exposure.

Due to the inorganic protective layer provided on the resist layer according to this embodiment of the invention, no contamination of resist layer material by contaminants comprised in the immersion liquid can occur. Furthermore, in contrast to conventional immersion lithography, immersion liquid materials other than deionized water can be used since the immersion liquid molecules can no longer enter the resist material due to the presence of the inorganic layer 5. Accordingly, the inorganic layer enables the use of kinds of immersion liquids that conventionally cannot be applied due to undesired chemical reactions or contaminations within the resist material.

The inorganic layer 5 may be formed of aluminum oxide or aluminum or any other metal, metal alloy, metal oxide or metal alloy oxide.

According to FIG. 10 the semiconductor product 1 is provided on a scanning stage 23 in order to expose a plurality of wafer surface regions one after the other. The scanning stage may form part of a stepping and/or scanning tool. Immersion lithography may for instance be applied when using an exposure wavelength of 193 or 157 nm. Independently from the small thickness of the inorganic layer 5, the material of the inorganic layer 5 may be chosen such that it is transparent in the range of wavelengths used for exposing the resist layer. Accordingly, transparency of the inorganic layer may result from both the transparent material properties of the inorganic material as well as from the small thickness of the inorganic layer.

Due to the contact between the resist material of the resist layer 4 and the inorganic material of the inorganic layer 5 all over of the top surface of the resist layer 4, outdiffusion and contamination of the resist material are prevented efficiently. The chemically inert inorganic layer serving as a sealing layer or protective layer increases the process window for lithographically exposing the resist layer is increased significantly and occurrence of defective structures like bridgings is produced significantly.

The embodiments of the invention efficiently prevent diffusion from or to a resist layer and outgassing of a resist layer. Due to the composition of organic materials like polymers (required for forming photoactive molecules), the resist layer may be subjected to outdiffusion of constituents of the resist material and to contamination with particles entering into the resist material from the ambient air or atmosphere. The outgassing components may further contaminate the optical surfaces of the lithography system (e.g., lense surfaces), thus reducing the process window and requiring increased efforts for maintenance of the lithographic system. Since the acid molecules to be formed upon exposure of the resist material are required for dissolving the resist layer upon exposure, the concentration of acid molecules essentially influences the process of dissolving the resist material. However, in case that the ambient air or atmosphere contains alkalic components able to react with the acid molecules or its predecessor molecules, the acid molecule concentration is influenced by contaminations in the ambient atmosphere. Since contaminations from the atmosphere may enter the resist material prior to and during the exposure, the process window for exposing and developing the resist layer is reduced. Thereby defective microelectronic elements (like bridgings of maintained resist material where expected to be removed) may conventionally occur. The embodiments of the present invention efficiently overcome all these drawbacks and enables formation of more inert resist layers and increases the process window.

What is claimed is:

1. A method of forming a patterned resist layer for patterning a substrate, the method comprising:
forming a resist layer on or above a substrate;
forming an inorganic layer over the resist layer;
lithographically exposing the resist layer covered with the inorganic layer; and
patterning the resist layer covered with the inorganic layer by etching, thereby forming a patterned resist layer.

2. The method of claim 1, wherein the substrate comprises a substrate of a semiconductor product.

3. The method of claim 1, wherein the substrate comprises a substrate of a reticle mask.

4. The method of claim 1, wherein the inorganic layer comprises a metal and/or a metal oxide.

5. The method of claim 1, wherein the inorganic layer has a thickness of between about 0.25 and 20 nm.

6. The method of claim 1, wherein the resist layer comprises an organic material.

7. The method of claim 1, wherein the inorganic layer is formed over the resist layer by means of physical vapor deposition, chemical vapor deposition or atomic layer deposition.

8. The method of claim 7, wherein the inorganic layer is formed on the resist layer by means of sputter deposition or evaporation.

9. The method of claim 8, wherein the inorganic layer is formed by depositing a metal on the resist layer to form a metal layer and by subsequently partially or completely converting the metal layer into the inorganic layer.

10. The method of claim 9, wherein the inorganic layer is formed by depositing a metal layer on the resist layer and by oxidizing the metal layer, thereby obtaining an oxide layer.

11. The method of claim 8, wherein the inorganic layer is formed on the resist layer by means of reactive sputter deposition.

12. The method of claim 11, wherein the reactive sputter deposition is performed using oxygen or nitrogen or a combination thereof as a reactive sputter gas component.

13. The method of claim 1, wherein the inorganic layer is formed on the resist layer by means of spin coating.

14. The method of claim 1, wherein the inorganic layer comprises at least one element selected from the group consisting of Al, Mg, Hf, Ba, Ni, Co, Fe, Ru, Ta, Ti, W and of the alloys and oxides thereof.

15. The method of claim 14, wherein the inorganic layer is made of at least one element selected from the group consisting of Al, Al₂O₃, MgO, HfOₓ, BaO, RuOₓ, NiFe and CoFe.

16. The method of claim 1, wherein the resist layer is lithographically exposed by means of electromagnetic radiation.

17. The method of claim 1, wherein the method further comprises patterning the substrate by etching the substrate or a layer over the substrate through the patterned resist layer serving as a mask layer.

18. The method of claim 17, wherein the method further comprises removing the patterned resist layer after patterning the substrate or patterning a layer over the substrate.

19. The method of claim 1, wherein patterning the resist layer includes patterning the inorganic layer before patterning the resist layer.

20. The method of claim 1, wherein exposing the resist layer comprises applying an immersion liquid on the inorganic layer and transmitting electromagnetic radiation through the immersion liquid and through the inorganic layer into the resist layer.

21. The method of claim 20, wherein the immersion liquid comprises deionized water or a fluid medium having a higher refractive index than water.

22. A method of making a semiconductor drive the method comprising:
forming a layer over a substrate;
forming a mask layer over the layer;
wherein forming the mask layer comprises:
depositing a resist layer made of organic resist material over the layer; and
depositing an inorganic layer made of inorganic material over the resist layer.

23. The method of claim 22, wherein the method further comprises patterning the inorganic layer and patterning the resist layer, thereby obtaining a patterned mask.

24. The method of claim 23, wherein the method further comprises patterning the layer by etching the layer through the patterned mask.

25. The method of claim 24, wherein the inorganic layer comprises a coating having a thickness of between 0.25 to 20 nm and wherein the inorganic layer comprises at least one element selected from the group consisting of Al, Mg, Hf, Ba, Ni, Co, Fe, Ru, Ta, Ti, W and of the alloys and oxides thereof.

26. The method of claim 25, wherein the inorganic layer comprises a coating having a thickness of between 1 and 3 nm.

27. A method of making a semiconductor device, the method comprising:
depositing an organic resist layer over a substrate or over a layer disposed over the substrate;
depositing an inorganic coating as a protection layer over the organic resist layer, thereby obtaining a coated mask;
lithographically exposing the organic resist layer covered with the inorganic coating;
patterning the inorganic coating and the organic resist layer, thereby obtaining a patterned coated mask; and
affecting the substrate or the layer disposed over the substrate using the patterned coated mask.

28. The method of claim 27, wherein affecting the substrate comprises etching the substrate or the layer over the substrate through the patterned coated mask.

29. The method of claim 27, wherein lithographically exposing the organic resist layer includes exposing the substrate covered with the coated mask to a vacuum or to a low pressure atmosphere.

30. An intermediate semiconductor product comprising:
a substrate;
at least one layer arranged over the substrate;
a resist layer arranged over the at least one layer; and
an inorganic layer over the resist layer.

31. The semiconductor product of claim 30, wherein the inorganic layer is a patterned inorganic layer.

32. The semiconductor product of claim 31, wherein the resist layer is a patterned resist layer.

33. The semiconductor product of claim 30, wherein the inorganic layer comprises a thickness smaller than a thickness of the resist layer, the thickness of the inorganic layer ranging between 0.25 and 20 nm.

34. The semiconductor product of claim 30, wherein the inorganic layer comprises a material selected from the group consisting of Al, Mg, Hf, Ba, Ni, Co, Fe and of the alloys and oxides thereof.

35. The semiconductor product of claim 30, wherein the inorganic layer comprises at least one element selected from the group consisting of Al, Al₂O₃, MgO, HfOₓ, BaO, RuOₓ, NiFe and CoFe.
